(19) United States
(12) Patent Application Publication
(10) Pub. No.: US 2023/0022624 A1
(43) Pub. Date: Jan. 26, 2023

(54) METHOD FOR PROCESSING SEMICONDUCTOR STRUCTURE

(71) Applicant: CHANGXIN MEMORY TECHNOLOGIES, INC., Hefei (CN)

(72) Inventor: Ning XI, Hefei (CN)

(73) Assignee: CHANGXIN MEMORY TECHNOLOGIES, INC., Hefei (CN)

(21) Appl. No.: 17/453,837

(22) Filed: Nov. 5, 2021

Related U.S. Application Data
(63) Continuation of application No. PCT/CN2021/117283, filed on Sep. 8, 2021.

(30) Foreign Application Priority Data
Jul. 20, 2021 (CN) 202110821481.2

(51) Int. Cl. H01L 21/02; H01J 37/32

(52) U.S. Cl. CPC H01L 21/02057; H01J 37/3244; H01J 37/32522; H01L 21/02164; H01J 2237/2001; H01J 2237/3355

(57) ABSTRACT

A method for processing a semiconductor structure includes: a substrate is provided, which has feature parts, in which an aspect ratio of the feature parts is greater than a preset aspect ratio, a barrier layer is disposed on tops of the feature parts, a hydrophilic layer is disposed on side walls of the feature parts, and there are particulate impurities on a surface of the hydrophilic layer; at least one cleaning treatment to the substrate is performed, in which the cleaning treatment includes: initial water vapor is introduced to the side walls of the feature parts, and a cooling treatment is performed to liquefy the initial water vapor adhering to a surface of the hydrophilic layer into water which carries the particulate impurities and flows into grooves; and a heating treatment is performed to evaporate the water into water vapor which carries the particulate impurities and escapes.

### CROSS-REFERENCE TO RELATED APPLICATIONS

This application is a continuation of International Application No. PCT/CN2021/117283 filed on Sep. 8, 2021, which claims priority to Chinese Patent Application No. 202110821481.2 filed on Jul. 20, 2021. The disclosures of the above-referenced applications are hereby incorporated by reference in their entirety.

### BACKGROUND

In a semiconductor manufacturing process, multiple processing steps, such as material deposition, flattening, feature patterning, etching and cleaning, are usually required. As the integrated circuit manufacturing technology node continues to shrink, the manufacturing technology is becoming more and more complex, and a structure with a high aspect ratio (HAR) is becoming more and more important. Due to the shrinking of the technology node, the depth of feature parts remains unchanged and the width thereof becomes smaller, or the depth of the feature parts becomes deeper and the width becomes smaller, resulting in an increase in the aspect ratio of the feature parts.

### SUMMARY

The disclosure relates to the field of semiconductor manufacture, and relates to a method for processing a semiconductor structure.

The embodiments of the disclosure provide a method for processing a semiconductor structure, including the following operations. A substrate is provided, which has feature parts, in which an aspect ratio of the feature parts is greater than a preset aspect ratio, a barrier layer is disposed on tops of the feature parts, a hydrophilic layer is disposed on side walls of the feature parts, and there are particulate impurities on a surface of the hydrophilic layer. At least one cleaning treatment to the substrate is performed, in which the cleaning treatment includes: introducing initial water vapor to the side walls of the feature parts, and performing a cooling treatment to liquefy the initial water vapor adhering to the surface of the hydrophilic layer into water which carries the particulate impurities and flows into grooves. A heating treatment is performed to evaporate the water into water vapor which carries the particulate impurities and escapes.

### BRIEF DESCRIPTION OF THE DRAWINGS

FIG. 1 is a first schematic structural diagram corresponding to an operation in a method for processing a semiconductor structure provided in some embodiments.

FIG. 2 is a second schematic structural diagram corresponding to an operation in a method for processing a semiconductor structure provided in some embodiments.

FIG. 3 is a third schematic structural diagram corresponding to an operation in a method for processing a semiconductor structure provided in some embodiments.

FIG. 4 is a fourth schematic structural diagram corresponding to an operation in a method for processing a semiconductor structure provided in some embodiments.

FIG. 5 is a schematic enlarged diagram of a groove in a method for processing a semiconductor structure provided in some embodiments.

FIG. 6 is a first schematic structural diagram corresponding to a hydrophilic treatment process provided in some embodiments.

FIG. 7 is a second schematic structural diagram corresponding to a hydrophilic treatment process provided in some embodiments.

FIG. 8 is a schematic structural diagram corresponding to another hydrophilic treatment process provided in some embodiments.

FIG. 9 is a schematic structural diagram corresponding to yet another hydrophilic treatment process provided in some embodiments.

FIG. 10 is a first schematic structural diagram corresponding to an operation in a cleaning treatment provided in some embodiments of the disclosure.

FIG. 11 is a second schematic structural diagram corresponding to an operation in a cleaning treatment provided in some embodiments of the disclosure.

FIG. 12 is a third schematic structural diagram corresponding to an operation in a cleaning treatment provided in some embodiments of the disclosure.

FIG. 13 is a schematic diagram illustrating a process of cleaning particulate impurities on surfaces of grooves provided in some embodiments.

### DETAILED DESCRIPTION

With the increase of integration level of semiconductors, use of a structure with an HAR has become more common. In each of the embodiments of the disclosure, a feature part is a substrate between grooves, formed by patterning part of the substrate, and the feature part is a structure with an HAR. Specifically, the structure with an HAR is a semiconductor structure of which the aspect ratio is at least greater than 10:1.

In a process for cleaning a structure with an HAR, the tilt of the structure with an HAR due to a capillary force is a serious problem and may cause semiconductor defects. Especially in the semiconductor manufacturing process of a structure with an HAR of 10 or more, during a cleaning and drying treatment, the capillary force may cause the structure with an HAR to tilt or even collapse, and the higher the aspect ratio, the more serious the tilt.

Methods for reducing the tilt of a structure with an HAR have been developed and applied. For example, supercritical carbon dioxide is used for drying in a wafer cleaning process. This technology is extremely expensive and usually requires accurate control, so that this technology is not suitable for industrial mass production. Therefore, at present, there is an urgent need for a method for cleaning a semiconductor structure with an HAR, which can reduce the problem of structure tilt caused by cleaning the structure with an HAR, and is suitable for industrial mass production.

The embodiments of the disclosure provide a method for processing the semiconductor structure, including the following operations. A substrate is provided, in which a barrier layer is formed on a top surface of the substrate. The barrier layer and a part of thickness of the substrate are patterned to form grooves, in which there are particulate impurities in the grooves. A hydrophilic treatment is performed on the surfaces of the grooves to improve hydrophilicity of the surfaces of the grooves. At least one cleaning treatment is performed on the remaining substrate. The cleaning treatment includes that initial water vapor is introduced into the grooves, and a cooling treatment is performed so that the initial water vapor adhering to the surfaces of the grooves is liquefied into water which carries the particulate impurities and flows into the grooves. A heating treatment is performed so that the water is evaporated into water vapor which carries the particulate impurities and escapes.

A person of ordinary skill in the art can understand that in the embodiments of the disclosure, many technical details are proposed for readers to better understand the disclosure. However, even without these technical details and various changes and modifications based on the following embodiments, the technical solutions claimed in the application can also be implemented.

A structure with an HAR is prone to problems such as lateral bending, changes in top feature size and bottom feature size, necking, tilting and graphic distortion due to the influence of pressures during a wet cleaning process. How to improve the cleaning quality of a structure with an HAR and prevent the same from tilting is a problem to be solved urgently at present.

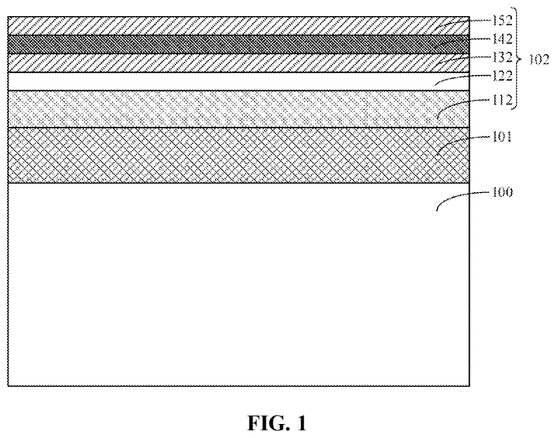

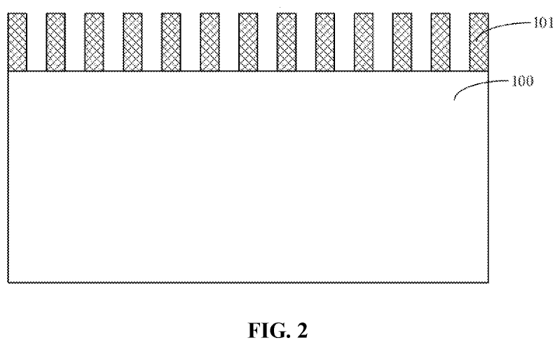

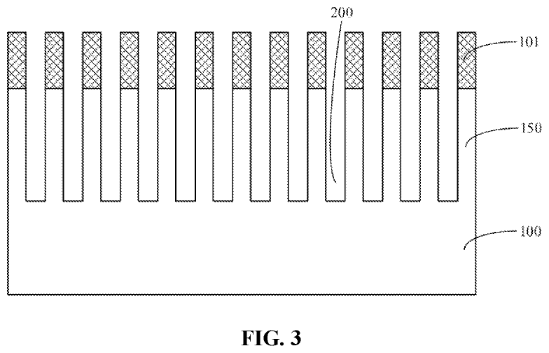

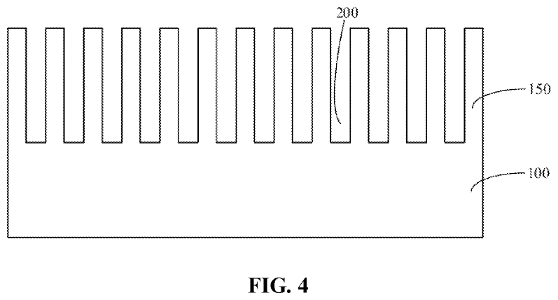

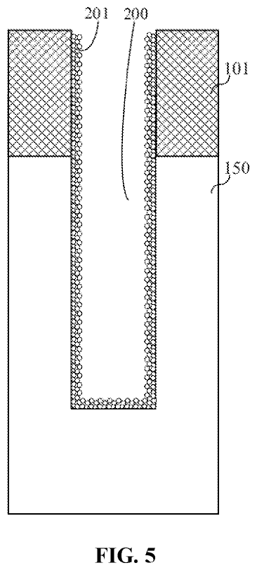

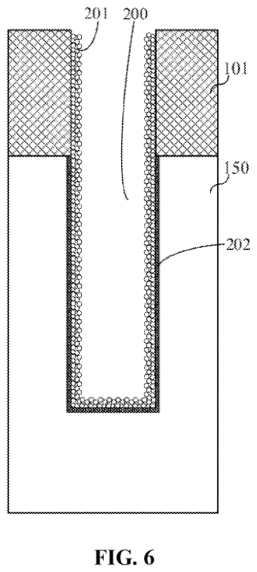

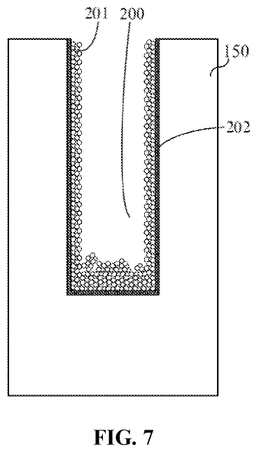

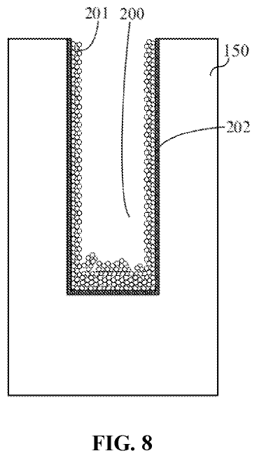

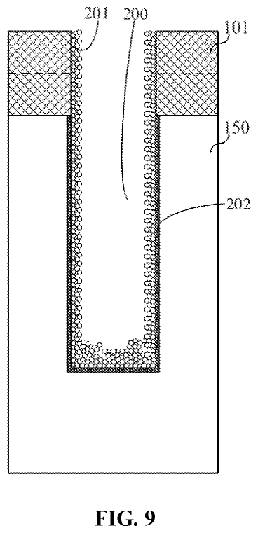

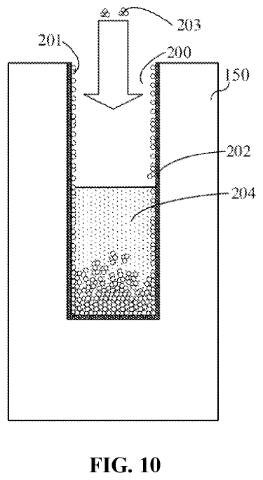

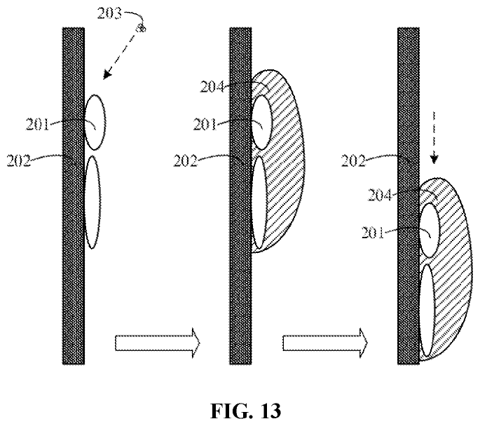

FIG. 1 to FIG. 4 are schematic structural diagrams corresponding to each of the operations in a method for processing a semiconductor structure. FIG. 5 is a schematic enlarged diagram of a groove in a method for processing a semiconductor structure. FIG. 6 and FIG. 7 are schematic structural diagrams corresponding to a hydrophilic treatment process. FIG. 8 is a schematic structural diagram corresponding to another hydrophilic treatment process. FIG. 9 is a schematic structural diagram corresponding to yet another hydrophilic treatment process. FIG. 10 to FIG. 12 are schematic structural diagrams corresponding to each of the operations in a cleaning treatment. FIG. 13 is a principle diagram of cleaning particulate impurities on the surfaces of grooves. The method for processing a semiconductor structure, provided by each of the embodiments of the disclosure, will be further described in detail below with reference to the drawings. The method is specifically as follows:

Referring to FIG. 1 to FIG. 4, a substrate 100 is provided. The substrate 100 has feature parts 150, the aspect ratio of the feature parts 150 is greater than a preset aspect ratio, a barrier layer 101 is disposed on the top of the feature parts 150, a hydrophilic layer 202 is disposed on the side walls of the feature parts 150 (referring to FIG. 6 to FIG. 9), and there are particulate impurities 201 adhered to the surface of the hydrophilic layer 202 (referring to FIG. 6 to FIG. 9).

Specifically, referring to FIG. 1 to FIG. 3, a method for forming the feature parts 150 includes the following operations. A substrate 100 is provided, a barrier layer 101 is formed on a top surface of the substrate, the barrier layer 101 and a part of thickness of the substrate 100 are patterned to form grooves 200, and the remaining substrate 100 between adjacent grooves 200 constitutes the feature parts 150.

In some embodiments, the substrate 100 is composed of a semiconductor material such as silicon or germanium. In this embodiment, the substrate 100 is formed with a material of silicon.

In this embodiment, the material of the barrier layer 101 is a boron amorphous carbon layer (BACL). In other embodiments, the material of the barrier layer 101 may also be an amorphous carbon layer (ACL), SiO₂ (silicon oxide) or SiN (silicon nitride).

In this embodiment, the depth of the formed grooves 200 is H, that is, the height of the feature parts 150 is H. The distance between adjacent grooves 200 is S, that is, the width of the feature parts 150 is S. That is, the aspect ratio of the formed feature parts 150 is H/S, and H/S is greater than a preset aspect ratio. In some embodiments, the preset aspect ratio is not less than 10, that is, the formed feature parts 150 are structures with an HAR. In this embodiment, the preset aspect ratio is 10. In other embodiments, the preset aspect ratio may be 12, 15, 18 or 20. In specific applications, the aspect ratio of the feature parts 150 is set according to actual needs.

Those skilled in the art can know that the limitation on the aspect ratio of the feature parts 150 in the embodiments of the disclosure is to define the problem that in the subsequent drying process, the wet cleaning treatment is likely to cause the tilt of the feature parts 150 with the aspect ratio, and all technical solutions for solving this problem with the limitation of the aspect ratio should fall within the protection scope of the disclosure. In addition, in some other embodiments, the preset aspect ratio may also be any value, that is, the method for processing a semiconductor structure provided by the disclosure is suitable for cleaning structures with any aspect ratio.

The barrier layer 101 and a part of thickness of the substrate 100 are patterned to form grooves 200, specifically including: a patterned mask layer 102 is formed on a top surface of the barrier layer 101; based on the patterned mask layer 102, the barrier layer 101 is patterned until the surface of the substrate 100 is exposed; and based on the patterned mask layer 102, a part of thickness of the substrate 100 is patterned to form the grooves 200.

The patterned mask layer 102 is formed on the top surface of the barrier layer 101. Referring to FIG. 1, in this embodiment, the patterned mask layer 102 includes: a first mask layer 112, a second mask layer 122, a third mask layer 132, a fourth mask layer 142 and a fifth mask layer 152 which are located on the barrier layer 101 in sequence.

Specifically, the material of the first mask layer 112 is Poly (polysilicon), the material of the second mask layer 122 is ACL, the materials of the third mask layer 132 and the fifth mask layer 152 are SiON (silicon oxynitride), and the material of the fourth mask layer 143 is SOC (spin on coat). The patterned mask layer 102 is configured to perform selective etching of the barrier layer 101 and the substrate 100.

It should be noted that the above description of the specific structure of the mask layer 102 is only used to illustrate the specific structure of the mask layer 102 provided in this embodiment, and does not constitute a limitation to other embodiments of the disclosure. In other embodiments, mask layers of other structures may also be used. The mask layer of any structure for forming the feature parts 150 by patterning should fall within the protection scope of the disclosure.

Based on the patterned mask layer 102, the barrier layer 101 is patterned until the surface of the substrate 100 is exposed.

The remaining barrier layer is the patterned barrier layer 101, and the pattern in the patterned barrier layer 101 is consistent with that in the patterned mask layer 102.

Based on the patterned mask layer 102, a part of thickness of the substrate 100 is patterned to form the grooves 200.

Referring to FIG. 5, particulate impurities 201 adhere to the side walls of a formed groove 200. The particulate impurities 201 include impurities such as etching residues in a patterning process.

The patterned mask layer 102 is removed. It should be noted that the operation of removing the patterned mask layer 102 may be performed after the grooves 200 are formed, or may be performed after the patterned barrier layer 101 is formed. In this embodiment, since the material of the barrier layer 101 is the BACL and the material of the first mask layer 112 is polysilicon, the etching selection ratio of the BACL to the polysilicon is relatively large. According to the concentration of boron doped in the BACL, the etching selection ratio of the BACL to the polysilicon is 50:1 to 300:1. That is, since the etching selection ratio of the BACL to the polysilicon is relatively large, the process of patterning a part of thickness of the substrate 100 can be implemented by etching based on the patterned barrier layer 101 as a mask. Specifically, in some embodiments, by controlling the concentration of boron doped in the BACL, the etching selection ratio of the BACL to the relatively large is 100:1, 150:1, 200:1, or 250:1.

Referring to FIG. 6 to FIG. 9, a process for forming the hydrophilic layer 202 includes that a hydrophilic treatment is performed on the side walls of the feature parts 150 to form the hydrophilic layer 202; and the barrier layer 101 is removed, and purge gas is introduced.

The hydrophilic treatment and the process of removing the barrier layer 101 may be performed step by step, or may be performed in the same process step. The hydrophilic layer 202 is formed after the hydrophilic treatment. It should be noted that in this embodiment, the material of the substrate 100 is silicon. Correspondingly, the material of the hydrophilic layer 202 is silicon oxide which has hydrophilicity, and the surface of the silicon oxide easily adsorbs water molecules.

In an example, referring to FIG. 6 and FIG. 7, the hydrophilic treatment is performed first to form the hydrophilic layer 202. After the hydrophilic layer 202 is formed and before the cleaning treatment is performed, the method further includes that the barrier layer 101 is removed, and the purge gas is introduced.

Specifically, the operation that the hydrophilic treatment is performed on the side walls of the feature parts 150 includes that water vapor and carrier gas are introduced to the side walls of the feature parts 150, and the water vapor is subjected to a treatment of forming a plasma during introducing the water vapor.

In some embodiments, the carrier gas may specifically be one of N₂ (nitrogen), Ar (argon) and He (helium). In this example, the carrier gas is Ar (argon). The flow rate of the introduced carrier gas ranges from 100 sccm to 5000 sccm, and specifically may be 1000 sccm, 2000 sccm, 3000 sccm or 4000 sccm. In this example, the flow rate of the introduced carrier gas is 2500 sccm.

In some embodiments, the treatment power of plasma treatment ranges from 1000 W to 8000 W, and specifically may be 2000 W, 4000 W or 6000 W. In this example, the treatment power of plasma treatment is 4500 W.

In some embodiments, the gas flow rate of the introduced water vapor ranges from 10 sccm to 300 sccm, and specifically may be 150 sccm, 200 sccm or 250 sccm. In this example, the gas flow rate of the introduced water vapor is 155 sccm.

If the material of the barrier layer 101 is the BACL, water vapor is introduced continuously to serve as the etching gas to remove the barrier layer 101. If the material of the barrier layer 101 is the ACL, SiO₂ or SiN, the etching gas introduced to remove the barrier layer 101 includes at least one of CF₄, C₄F₈, C₄F₆, CHF₃, CH₂F₂, or CH₃F.

Specifically, in the process of removing the barrier layer 101, the pressure of the reaction environment ranges from 0 mTorr to 10000 mTorr, and specifically may be 3000 mTorr, 6000 mTorr or 9000 mTorr. In this example, the pressure of the reaction environment is 5000 mTorr, and the temperature of the substrate 100 ranges from 20° C. to 100° C., and specifically may be 40° C., 60° C. or 80° C. In this example, the temperature of the substrate 100 is 60° C., and the temperature of the water vapor ranges from 100° C. to 250° C., and specifically may be 130° C., 170° C., 200° C. or 230° C. In this example, the temperature of the water vapor is 175° C.

Specifically, the temperature of the substrate 100 is controlled by a chuck, the chuck is used to carry the substrate 100 in a reaction chamber, and the temperature of the substrate 100 placed on the chuck is indirectly controlled by controlling the temperature of the chuck. The temperature of the substrate 100 ranges from 20° C. to 100° C., that is, the temperature of the chuck ranges from 20° C. to 100° C. The temperature of the water vapor is controlled by a gas pipeline, and the gas pipeline is used to introduce the reaction gas reacting with the substrate 100 into the reaction chamber, thereby controlling the temperature of the gas pipeline to indirectly control the temperature of the reaction gas introduced into the reaction chamber. In this example, the temperature of the water vapor is indirectly controlled, and the temperature of the water vapor ranges from 100° C. to 250° C., that is, the temperature of the gas pipeline ranges from 100° C. to 250° C. In addition, in this example, the temperature of the chamber walls of the reaction chamber ranges from 100° C. to 150° C. to prevent water vapor from condensing on the chamber walls of the reaction chamber. Specifically, the temperature of the chamber walls of the reaction chamber may be 110° C., 120° C., 130° C. or 140° C. In this example, the temperature of the chamber walls of the reaction chamber is 125° C.

In some embodiments, the flow rate of the introduced etching gas ranges from 10 sccm to 300 sccm, and specifically may be 150 sccm, 200 sccm or 250 sccm. In this example, the flow rate of the introduced etching gas is 155 sccm.

In another example, referring to FIG. 8, the removal of the barrier layer 101 and the hydrophilic treatment on the side walls of the feature parts 150 are implemented in the same process step, that is, the hydrophilic treatment is performed on the side walls of the feature parts 150 and the barrier layer 101 is removed at the same time. In the process of removing the barrier layer 101, the hydrophilic layer 202 is formed.

Specifically, the process of performing hydrophilic treatment on the side walls of the feature parts 150 and removing the barrier layer 101 includes that water vapor and carrier gas are introduced into the side walls of the feature parts 150, and a treatment is performed on the water vapor to form plasma during introducing the water vapor.

In this example, the flow rate of the introduced carrier gas is 2500 sccm. The treatment power of plasma treatment is 4500 W. In this example, the gas flow rate of the introduced water vapor is 155 sccm.

In this example, on the premise that the material of the barrier layer 101 is the BACL, water vapor is used to perform hydrophilic treatment and remove the barrier layer 101 at the same time. The gas flow rate of the introduced water vapor ranges from 10 sccm to 300 sccm, and specifically may be 150 sccm, 200 sccm or 250 sccm. In this example, the gas flow rate of the introduced water vapor is 155 sccm.

In this example, in the process of performing hydrophilic treatment on the side walls of the feature parts 150 and removing the barrier layer 101, the pressure of the reaction environment is 5000 mTorr, the temperature of the substrate 100 is 60° C., and the temperature of the water vapor is 175° C.

In another example, referring to FIG. 9, the hydrophilic treatment is first performed to form the hydrophilic layer 202, and the process of removing the barrier layer 101 is performed at the same time when performing the cyclic procedure of the cleaning treatment. That is, before each round of cleaning treatment is performed, a part of the barrier layer 101 is removed, and before the last round of cleaning treatment is performed, the remaining barrier layer 101 is removed.

Referring to FIG. 10 to FIG. 13, after the hydrophilic layer 202 is formed, at least one cleaning treatment is performed on the substrate 100. The cleaning treatment includes that initial water vapor 203 is introduced to the side walls of the feature parts 150, and cooling treatment is performed so that the initial water vapor 203 adhering to the surface of the hydrophilic layer 202 is liquefied into water 204 which carries particulate impurities 201 and flows into the groove 200; and heating treatment is performed so that the water is evaporated into the water vapor 203 which carries the particulate impurities 201 and escapes.

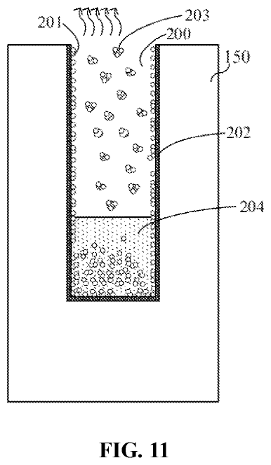

Specifically, referring to FIG. 10, the water vapor 203 is introduced into a groove 200 and the cooling treatment is performed, water molecules adhere to the surfaces of the groove 200 and accumulate continuously and slide down the side walls of the groove 200 in the form of liquid water, and the liquid water carries the particulate impurities 201 on the side walls of the groove 200 and flows into the bottom of the groove 200, thereby transferring the particulate impurities 201 on the side walls of the groove 200 to the bottom of the groove 200. Referring to FIG. 11, after a period of time, heating treatment is performed, the liquid water 204 at the bottom of the groove 200 is evaporated into the water vapor 203, and in the evaporation process, the escaped water vapor 203 carries the particulate impurities 201 to escape together, thereby completing the cleaning of the impurities on the side walls of the groove 200.

Specifically, in some embodiments, the temperature after the cooling treatment ranges from 20° C. to 60° C., and specifically may be 30° C., 40° C. or 50° C. In this example, the temperature after the cooling treatment is 20° C., and the temperature after the heating treatment ranges from 60° C. to 100° C., and specifically may be 70° C., 80° C. or 90° C. In this example, the temperature after the heating treatment is 100° C., and the temperature change rate of the cooling treatment ranges from 0.5 s/° C. to 1.5 s/° C., and specifically may be 0.8 s/° C., 1.0 s/° C. or 1.2 s/° C. In this example, the temperature change rate of the cooling treatment is 1.0 s/° C., and the temperature change rate of the heating treatment ranges from 0.5 s/° C. to 1.5 s/° C., and specifically may be 0.8 s/° C., 1.0 s/° C. or 1.2 s/° C. In this example, the temperature change rate of the heating treatment is 1.0 s/° C.

In some embodiments, the flow rate of the introduced initial water vapor ranges from 1000 sccm to 20000 sccm, and specifically may be 4000 sccm, 7000 sccm, 10000 sccm, 13000 sccm or 16000 sccm. In this example, the flow rate of the introduced initial water vapor is 10000 sccm.

In addition, in some embodiments, the introduced purge gas is N₂ (nitrogen) or inert gas, and the purge time of the purge gas ranges from 20 s to 60 s, and specifically may be 30 s, 40 s or 50 s. The purpose of introducing the purge gas is to clean the reaction gas introduced in the process of performing the hydrophilic treatment and etching the barrier layer 101 or the impurity gas generated in reaction in the reaction chamber where the semiconductor structure is located.

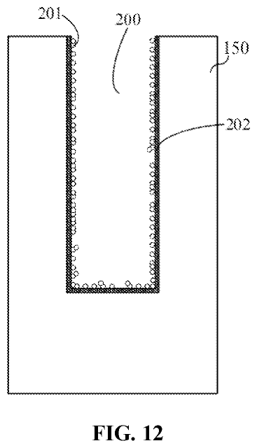

Referring to FIG. 10 and FIG. 12, after the cleaning treatment is performed, the particulate impurities 201 adhering to the surface of the hydrophilic layer 202 are partially cleaned. In addition, in some embodiments, at least one cleaning treatment is performed on the substrate, including that a preset number of times of the cleaning treatment is cyclically performed. The cleaning treatment is cyclically performed to ensure that the particulate impurities on the side walls of the groove 200 are completely cleaned.

Specifically, the preset number of times may be 3, 5, 7, etc., and the specific cyclic number of times may be set according to the specific impurity condition. It should be noted that the above example of the preset number of times does not constitute a limitation to each of the above embodiments.

With respect to FIG. 9, it is applied to cyclically perform a preset number of times of the cleaning treatment. Before the water vapor is introduced into the groove 200, the cleaning treatment further includes that a part of thickness of the barrier layer 101 is removed, and a purge gas is introduced; and in the process of performing last cleaning treatment, the removal of a part of thickness of the barrier layer 101 is removal of the barrier layer 101. The height of the patterned barrier layer 101 shown in FIG. 9 is obtained after one cleaning treatment, and the remaining patterned barrier layer 101 also needs to be subjected to two times of the cleaning treatment. In other words, in this example, a total of three rounds of cleaning treatment needs to be performed, that is, the preset number of times is 3.

In some embodiments, after the cleaning treatment is performed, the hydrophilic layer 202 formed by hydrophilic treatment on the surface of the groove 200 is removed.

Specifically, a chemical process is used to remove the hydrophilic layer 202, and the chemical gas used in the chemical process has an etching selection ratio greater than 500:1 of the hydrophilic layer 202 to the remaining substrate 100. The chemical gas with a larger etching selection ratio is used to prevent the remaining substrate 100 from being etched as much as possible in the process of removing the hydrophilic layer 202.

A chemical method for removing the hydrophilic layer 202 includes that NH₃ and HF are introduced, and a first temperature treatment is performed; and N₂ is introduced, and a second temperature treatment is performed. The temperature after the first temperature treatment ranges from 20° C. to 40° C., and the temperature after the second temperature treatment ranges from 100° C. to 200° C.

At this time, the reactions between the hydrophilic layer 202 and NH₃ and HF as follows:

SiO₂+4HF+4NH₃→SiF₄+2H₂O+4NH₃ (1),

SiF₄+2HF+2NH₃→(NH₄)₂SiF₆ (2).

In reaction (1), HF serves as a reactive gas to react with the hydrophilic layer 202 to generate SiF₄, and NH₃ serves as a catalyst to accelerate the reaction. In reaction (2), both NH₃ and HF serve as reactive gases and continue to react with SiF₄ generated in reaction (1) to generate volatile (NH₄)₂SiF₆ solids.

In some embodiments, in the process of introducing NH₃ (ammonia) and HF (hydrogen fluoride), Ar (argon) also needs to be introduced to serve as a carrier of NH₃ and HF. Ar (argon) is introduced as a carrier to ensure that NH₃ and HF fully react with the hydrophilic layer 202. In addition, Ar is introduced as a carrier gas which can prevent HF from condensing in an inlet pipeline.

Specifically, in reaction (1) and reaction (2), it is necessary to ensure that reactants are at the first temperature. The first temperature is the temperature after the first temperature treatment, which ranges from 20° C. to 40° C. In some embodiments, the first temperature may be 25° C., 30° C. or 35° C. In this example, the first temperature is 30° C. In the process of introducing N₂, it is necessary to ensure that the reactants are at the second temperature to better sublime (NH₄)₂SiF₆ solids. The purpose of introducing N₂ is that N₂ is introduced as a carrier gas to take out the volatilized (NH₄)₂SiF₆ solids. The second temperature is the temperature after the second temperature treatment, which ranges from 100° C. to 200° C. In some embodiments, the second temperature may be 120° C., 140° C., 160° C. or 180° C. In this example, the second temperature is 150° C.

In the process of cleaning the grooves, since the surface of the feature parts has a hydrophilic layer, water molecules easily adhere to the surface of the hydrophilic layer. In the cleaning process, water vapor is introduced into the grooves and a cooling treatment is performed, water molecules adhere to the surface of the hydrophilic layer and accumulate continuously and slide down the hydrophilic layer on the side walls of the feature parts in the form of liquid water, and the liquid water carries the particulate impurities on the surface of the hydrophilic layer and flows into the gaps between adjacent feature parts, thereby transferring the particulate impurities on the side walls of the feature parts to the bottom of the gaps between adjacent feature parts. After a period of time, a heating treatment is performed, the liquid water at the bottom of the gaps between adjacent feature parts is evaporated into water vapor, and in the evaporation process, and the escaped water vapor carries the particulate impurities to escape together, thereby completing the cleaning of the impurities on the side walls of the feature parts. The side walls of the feature parts are cleaned utilizing the state change of water to reduce the influence of surface tension on the structure with an HAR in the cleaning process, thereby avoiding the problem of tilting of the feature parts in the cleaning process.

The division of the above steps is only for clarity of description. When implemented, the steps can be combined into one step or some step can be split into multiple steps. As long as the steps include the same logical relationship, they are all within the protection scope of this application. Adding insignificant modifications or introducing insignificant designs to the process without changing the core design of the process are all within the protection scope of this application. A person of ordinary skill in the art can understand that the above embodiments are specific embodiments for implementing the disclosure. In practical applications, various changes can be made in forms and details without departing from the spirit and scope of the disclosure.

What is claimed is:

1. A method for processing a semiconductor structure, comprising:
providing a substrate, which has feature parts, wherein an aspect ratio of the feature parts is greater than a preset aspect ratio, a barrier layer is disposed on tops of the feature parts, a hydrophilic layer is disposed on side walls of the feature parts, and there are particulate impurities on a surface of the hydrophilic layer;
performing at least one cleaning treatment to the substrate, wherein the cleaning treatment comprises:
introducing initial water vapor to the side walls of the feature parts, and performing a cooling treatment to liquefy the initial water vapor adhering to the surface of the hydrophilic layer into water; and
performing a heating treatment to evaporate the water into water vapor which carries the particulate impurities and escapes.

2. The method for processing a semiconductor structure of claim 1, wherein a method for forming the hydrophilic layer comprises: performing a hydrophilic treatment on the side walls of the feature parts to form the hydrophilic layer.

3. The method for processing a semiconductor structure of claim 2, further comprising: after forming the hydrophilic layer and before performing the cleaning treatment, removing the barrier layer, and introducing purge gas.

4. The method for processing a semiconductor structure of claim 3, wherein removing the barrier layer and performing the hydrophilic treatment on the side walls of the feature parts are completed in a same process step.

5. The method for processing a semiconductor structure of claim 4, wherein performing the hydrophilic treatment on the side walls of the feature parts comprises:
introducing the water vapor and carrier gas to the side walls of the feature parts; and
subjecting the water vapor to a treatment of forming plasma during introducing the water vapor.

6. The method for processing a semiconductor structure of claim 5, wherein:
a gas flow rate of the introduced water vapor ranges from 10 sccm to 300 sccm; and
a flow rate of the introduced carrier gas ranges from 100 sccm to 5000 sccm.

7. The method for processing a semiconductor structure of claim 5, wherein in a process of removing the barrier layer:
a pressure of a reaction environment ranges from 0 mTorr to 10000 mTorr;
a temperature of the substrate ranges from 20° C. to 100° C.; and
a temperature of the introduced water vapor ranges from 100° C. to 250° C.

8. The method for processing a semiconductor structure of claim 1, wherein the preset aspect ratio is not less than 10.

9. The method for processing a semiconductor structure of claim 1, wherein during the cleaning treatment:
a flow rate of the introduced initial water vapor ranges from 1000 sccm to 20000 sccm;
a temperature after the cooling treatment ranges from 20° C. to 60° C.;
a temperature after the heating treatment ranges from 60° C. to 100° C.;
a temperature change rate of the cooling treatment ranges from 0.5 s/° C. to 1.5 s/° C.; and
a temperature change rate of the heating treatment ranges from 0.5 s/° C. to 1.5 s/° C.

10. The method for processing a semiconductor structure of claim 1, wherein,
performing at least one cleaning treatment to the substrate comprises: cyclically performing a preset number of times of the cleaning treatment;
wherein, the cleaning treatment further comprises: before introducing water vapor to the side walls of the feature part, removing a part of thickness of the barrier layer, and introducing purge gas; and
during performing a last cleaning treatment, removing a part of thickness of the barrier layer is: removing the barrier layer.

11. The method for processing a semiconductor structure of claim 1, wherein the barrier layer is an amorphous carbon layer doped with boron atoms.

12. The method for processing a semiconductor structure of claim 1, wherein a process for forming the feature parts comprises:
providing the substrate, and forming the barrier layer on a top surface of the substrate;
patterning the barrier layer and part of thickness of the substrate to form grooves, wherein the remaining substrate between adjacent grooves constitutes the feature parts; and
performing a hydrophilic treatment on surfaces of the grooves to form the hydrophilic layer.

13. The method for processing a semiconductor structure of claim 12, wherein patterning the barrier layer and part of thickness of the substrate to form the grooves comprises:
forming a patterned mask layer on a top surface of the barrier layer;
patterning the barrier layer based on the patterned mask layer until the surface of the substrate is exposed;
patterning part of thickness of the substrate to form the grooves based on the patterned mask layer; and
removing the patterned mask layer.

14. The method for processing a semiconductor structure of claim 1, further comprising: after the cleaning treatment, removing the hydrophilic layer, which comprises:
introducing NH₃ and HF, and performing a first temperature treatment; and
introducing N₂, and performing a second temperature treatment.

15. The method for processing a semiconductor structure of claim 14, wherein the temperature after the first temperature treatment ranges from 20° C. to 40° C., and the temperature after the second temperature treatment ranges from 100° C. to 200° C.
